(19) United States
(12) Patent Application Publication
(10) Pub. No.: US 2017/0245380 A1
(43) Pub. Date: Aug. 24, 2017

(54) THERMAL BARRIER INCLUDING AN AEROGEL BLANKET

(71) Applicant: TYCO ELECTRONICS CORPORATION, Berwyn, PA (US)

(72) Inventors: Hyo Chang Yun, Saratoga, CA (US); Thomas D. Ratzlaff, Menlo Park, CA (US); Ismael L. Sandoval, Fremont, CA (US); David A. Hurrell, San Mateo, CA (US); Bruce R. Conway, LaHonda, CA (US); Peter J. Dutton, Fremont, CA (US)

(21) Appl. No.: 15/047,381

(22) Filed: Feb. 18, 2016

(51) Int. Cl. H05K 5/02; H05K 5/03

(52) U.S. Cl. CPC H05K 5/0213; H05K 5/03

(57) ABSTRACT

A thermal barrier for an electronic component includes an aerogel blanket configured to cover at least a portion of the electronic component and a cover positioned between the aerogel blanket and the electronic component. The aerogel blanket has a top, a bottom and edges therebetween. The bottom is configured to face the electronic component. The cover is a structurally reinforcing fabric affixed to the bottom of the aerogel blanket. The cover inhibits dust migration from the aerogel blanket toward the electronic component.

### BACKGROUND OF THE INVENTION

The subject matter herein relates generally to thermal barriers for electronic components.

Thermal barriers are used to provide thermal protection for components, such as electronic components. For example, thermal barriers may be used for cables, electrical connectors, electrical devices, circuit boards, antennas, or other types of electronic components. In some applications, the thermal barriers and electronic components may be used in extreme environments and thus thermal barriers having excellent thermal performance may be needed. For example, some applications may be subject to extremely high temperatures, such as in excess of 400° C. or more, such as in excess of 1,000° C. In various applications, such as aeronautical applications, weight of the thermal barrier is a concern. In various applications, handling, flexibility and manipulability of the thermal barrier is a concern.

Aerogel is a material having very high thermally insulating properties making its use as a thermal barrier in some applications desirable. However, commercialization of aerogel has been limited due to the brittleness and poor processability of aerogel. Recently, aerogel blankets have been developed by consolidating aerogel particles with a flexible fiber textile, which combines the thermal properties of the aerogel with the workable properties of the flexible fiber textile. However, such aerogel blankets are not without disadvantages. For example, the aerogel particles are easily released by mild forces, such as bending and cutting. The released aerogel particles or dust generate a handling issue and potential functional issue to electronic devices. Dust control from aerogel blankets is problematic when used with electronic components. At least some known aerogel blankets mitigate dust creation by providing a polymer coating on the aerogel blanket, which may be applied by spraying or dipping the aerogel blanket to keep the aerogel particles within the blanket. However, at high temperatures, such as those over 400° C., the polymer coating is subject to thermal degradation. The polymer coating will degrade, such as due to melting, causing issues such as smoke and discoloration.

A need remains for a thermal barrier having excellent thermal properties without the dust and smoke issues of conventional thermal barriers.

### BRIEF SUMMARY OF THE INVENTION

In one embodiment, a thermal barrier for an electronic component includes an aerogel blanket configured to cover at least a portion of the electronic component and a cover positioned between the aerogel blanket and the electronic component. The aerogel blanket has a top, a bottom and edges therebetween. The bottom is configured to face the electronic component. The cover is a structurally reinforcing fabric affixed to the bottom of the aerogel blanket. The cover inhibits dust migration from the aerogel blanket toward the electronic component.

In a further embodiment, a thermal barrier for an electronic component includes an aerogel blanket configured to cover at least a portion of the electronic component and a cover affixed to the aerogel blanket. The aerogel blanket has a top, a bottom and edges therebetween. The bottom is configured to face the electronic component. The cover is positioned between the aerogel blanket and the electronic component. The cover has a top covering along the top of the aerogel blanket and the cover having a bottom covering along the bottom of the aerogel blanket. The top cover is sewn to the bottom cover through the aerogel blanket. The cover inhibits dust migration from the aerogel blanket to the electronic component.

In another embodiment, a thermal barrier for an electronic component includes an aerogel blanket configured to cover at least a portion of the electronic component and a cover affixed to the aerogel blanket such that the cover is positioned between the aerogel blanket and the electronic component. The aerogel blanket has a top, a bottom and edges therebetween. The bottom is configured to face the electronic component. The cover has a top covering along the top of the aerogel blanket and a bottom covering along the bottom of the aerogel blanket. The cover has an edge coating along the edges of the aerogel blanket between the top covering and the bottom covering. The cover inhibits dust migration from the aerogel blanket to the electronic component.

### BRIEF DESCRIPTION OF THE DRAWINGS

FIG. 1 is a schematic illustration of a thermal barrier for an electronic component formed in accordance with an exemplary embodiment.

FIG. 2 is a cross-sectional view of the thermal barrier formed in accordance with an exemplary embodiment.

FIG. 3 is a top view of the thermal barrier.

FIG. 4 is a cross-sectional view of the thermal barrier formed in accordance with an exemplary embodiment.

FIG. 5 is a top view of the thermal barrier shown in FIG. 4.

FIG. 6 is a cross-sectional view of the thermal barrier formed in accordance with an exemplary embodiment.

FIG. 7 is a cross-sectional view of the thermal barrier formed in accordance with an exemplary embodiment.

### DETAILED DESCRIPTION OF SPECIFIC EMBODIMENTS OF THE INVENTION

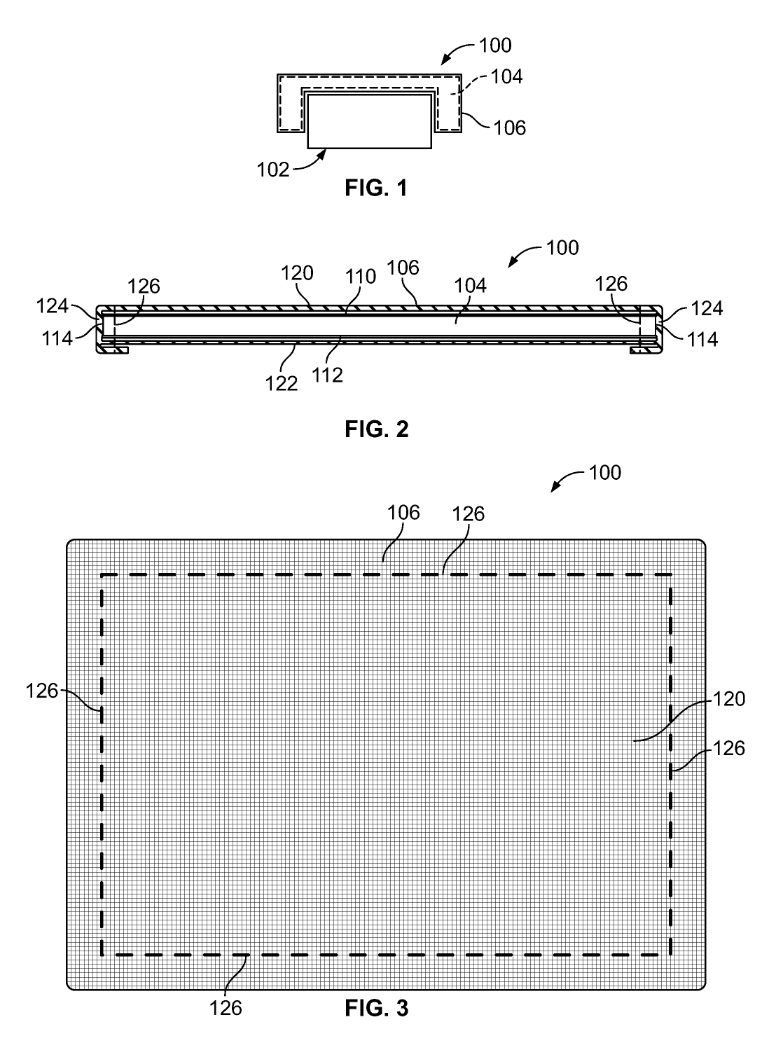

FIG. 1 is a schematic illustration of a thermal barrier 100 for an electronic component 102 formed in accordance with an exemplary embodiment. The thermal barrier 100 is used to protect the electronic component 102, such as from excessive heat or fire. For example, the thermal barrier 100 may be used to protect the electronic component 102 from exposure to extreme temperatures, such as above 400° C. or more, such as above 1,000° C. The thermal barrier 100 may be used with any type of electronic component 102, such as a cable, an electrical connector, an electrical device, a circuit board, an antenna, or other types of electronic components. The thermal barrier 100 and electronic component 102 may be used in various applications, such as, an aeronautical application, an industrial application, or another type of application.

The thermal barrier 100 is positioned relative to the electronic component 102 to protect the electronic component 102 from heat and/or fire. Optionally, the thermal barrier 100 may cover one or more sides of the electronic component 102. The thermal barrier 100 may completely cover the electronic component 102. Alternatively, the thermal barrier 100 may cover portions of the electronic component 102.

The thermal barrier 100 includes a thermal substrate 104 and a cover 106 covering at least a portion of the thermal substrate 104. The thermal substrate 104 is manufactured from a thermally insulative material to provide thermal protection for the electronic component 102. The cover 106 is used to provide protection for the thermal substrate 104 and/or the electronic component 102.

In an exemplary embodiment the thermal substrate 104 is manufactured from an aerogel material. For example, the thermal substrate 104 is an aerogel blanket and may be referred to hereinafter as an aerogel blanket 104. The aerogel blanket 104 includes aerogel particles and fibrous inorganic battings or textile. For example, the aerogel particles may be chemically bound to a ceramic fiber textile. The fibers are flexible and provide a structure that may be rolled, cut, sewn, shaped or manipulated around the electronic component 102. The aerogel particles have super-insulating properties to provide thermal protection and performance at extremely high temperatures. By combining the aerogel particles with the fiber textile, the aerogel blanket is processable and workable, such as for bending, cutting and handling.

The cover 106 inhibits dust migration from the aerogel blanket 104 during handling and use. The cover 106 obstructs dust that is shed or sloughed off of the aerogel blanket 104 from migrating or moving toward the electronic component 102. Optionally, the cover 106 may wrap entirely around the aerogel blanket 104 and retain the dust within the interior of the cover 106. In an exemplary embodiment, the cover 106 is affixed directly to the aerogel blanket 104. Alternatively, the cover 106 is positioned adjacent to the aerogel blanket 104 without being tied directly to the aerogel blanket 104.

The cover 106 is manufactured from a material capable of withstanding extreme temperatures, such as temperatures in excess of 400° C. or higher, such as in excess of 1,000° C. In an exemplary embodiment, the cover 106 is manufactured from a structurally reinforcing fabric, such as an inorganic fabric, a fiberglass fabric, a ceramic fabric, an inorganic film, or another type of structure. The cover 106 may be separately fabricated from the aerogel blanket 104 and affixed thereto. Optionally, the cover 106 may be sewn to the aerogel blanket 104 and/or to itself. The cover 106 may be affixed to the aerogel blanket 104 by other means in alternative embodiments, such as by using hot melt adhesive to affix the cover 106 to the aerogel blanket 104.

FIG. 2 is a cross-sectional view of the thermal barrier 100 formed in accordance with an exemplary embodiment. FIG. 3 is a top view of the thermal barrier 100. The thermal barrier 100 includes the cover 106 affixed to the aerogel blanket 104 (FIG. 2). In the illustrated embodiment, the cover 106 completely encloses the aerogel blanket 104; however, the cover 106 may cover only a portion or portions of the aerogel blanket 104 in alternative embodiments.

The aerogel blanket 104 includes a top 110, a bottom 112 and edges 114 between the top and bottom 110, 112. The aerogel blanket 104 has a thickness defined between the top 110 and the bottom 112. The aerogel blanket 104 includes aerogel particles and flexible fibers defining the structure of the aerogel blanket 104. Optionally, the top 110 and the bottom 112 may be generally planar and parallel; however, the top 110 and/or the bottom 112 may be nonplanar and/or nonparallel in alternative embodiments. The aerogel blanket 104 may have a non-uniform thickness in various embodiments. Optionally, the top 110 and/or the bottom 112 may have v-shaped grooves or channels formed therein to facilitate wrapping or folding the thermal barrier 100 around the electronic component 102 (show in FIG. 1).

The cover 106 includes a top covering 120, a bottom covering 122, and edge coverings 124. However, the cover 106 may include fewer coverings in alternative embodiments, such as only the bottom covering 122, only the top covering 120 or only the top and bottom coverings 120, 122 without the edge coverings 124. In an exemplary embodiment, the coverings 120, 122, 124 are structurally reinforcing fabrics. For example, the coverings 120, 122, 124 may be inorganic fabrics, fiberglass fabrics, ceramic fabrics, inorganic films, or other structures. Optionally, the coverings 120, 122, 124 may be formed from a single piece of fabric, which may be wrapped entirely around the aerogel blanket 104. Alternatively, the coverings 120, 122, 124 may be formed from multiple pieces of fabric, such as one piece of fabric for the top covering 120, and another piece of fabric for the bottom covering 122. The edge coverings 124 may be separate pieces or may be formed from the top covering 120 or the bottom covering 122.

The top covering 120 extends along and may be affixed to the top 110 of the aerogel blanket 104. The bottom covering 122 extends along and may be affixed to the bottom 112 of the aerogel blanket. The edge coverings 124 extend along and may be affixed to the edges 114 of the aerogel blanket 104. In an exemplary embodiment, the coverings 120, 122 and/or 124 may be affixed to the aerogel blanket 104 by sewing the respective coverings 120, 122 and/or 124 to the aerogel blanket 104 using stitching 126. The stitching 126 may be manufactured from a material capable of withstanding extreme temperatures, such as temperatures of approximately 1,000° C. For example, the stitching 126 may be ceramic fibers, fiberglass, or other types of materials. Optionally, the top covering 120 may be sewn to the bottom covering 122 through the aerogel blanket 104. For example, ends of the top covering 120 may wrap around the edges 114 to define the edge coverings 124, with the ends of the top covering 120 wrapping below the bottom covering 122 and being sewn using the stitching 126. Alternatively, the top covering 120 may be affixed to the aerogel blanket 104 independent of the bottom covering 122.

The coverings 120, 122, 124 may be affixed to the aerogel blanket 104 by other means in alternative embodiments. For example, hot melt adhesive may be used to affix the top covering 120 to the top 110, the bottom covering 122 to the bottom 112 and/or the edge coverings 124 to the edges 114.

The cover 106 is positioned relative to the electronic component 102 and the aerogel blanket 104 to provide protection for the electronic component 102, such as from dust created by handling of the aerogel blanket 104. The cover 106 is provided to inhibit dust migration from the aerogel blanket 104, which may otherwise interfere with or damage the electronic component 102. The bottom covering 122 may be positioned between the aerogel blanket 104 and the electronic component 102. In other embodiments, the top covering 120 is positioned between the aerogel blanket 104 and the electronic component 102. The cover 106 may completely enclose the aerogel blanket 104 to eliminate dust migration from the thermal barrier 100 into the environment around the thermal barrier 100.

The cover 106 is lightweight, such as compared to a metal housing or other structure used to contain the dust. The cover 106 may allow some airflow through the thermal barrier 100, which may reduce the temperature of the electronic component 102. Optionally, the cover 106 and the aerogel blank 104 are manufactured from materials that do not inhibit communication with the electronic component, such as RF communication.

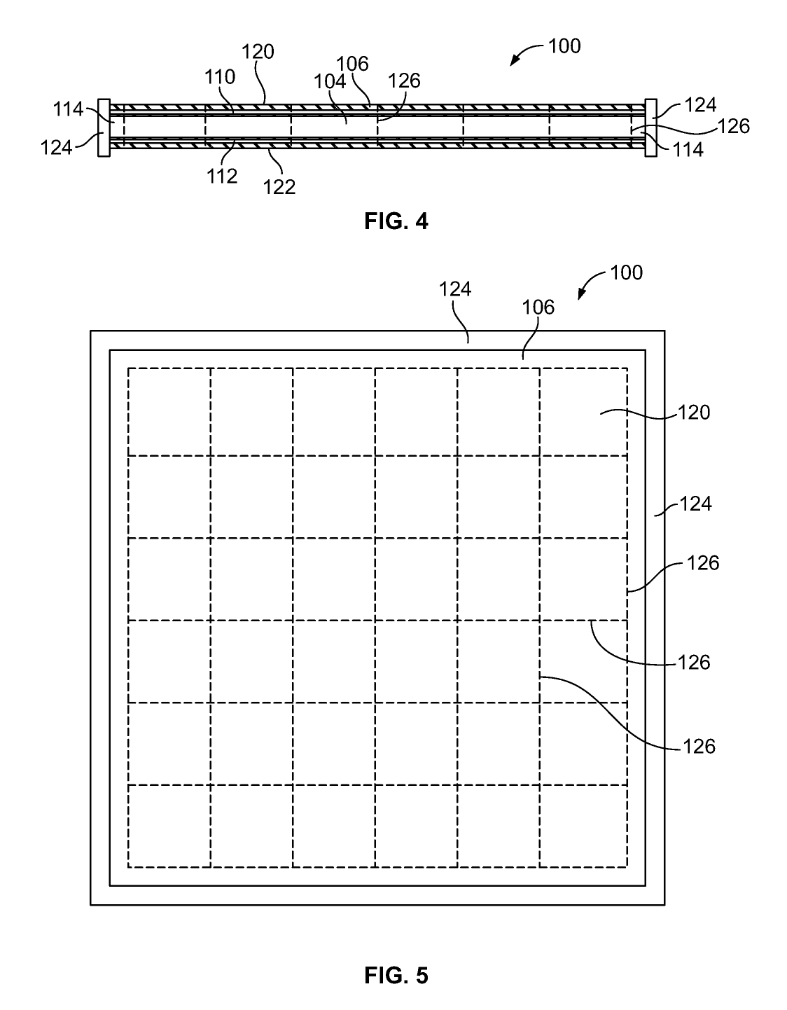

FIG. 4 is a cross-sectional view of the thermal barrier 100 showing the cover 106 with edge coverings 124 formed in accordance with an exemplary embodiment. FIG. 5 is a top view of the thermal barrier 100 with the edge coverings 124 shown in FIG. 4. The thermal barrier 100 includes the top covering 120 along the top 110 of the aerogel blanket 104 and the bottom covering 122 along the bottom 112 of the aerogel blanket 104. The edge coverings 124 are provided at the edges 114. In the illustrated embodiment, the edge coverings 124 are polymer coatings. For example, the edges 114 may be sprayed or dipped onto the edges 114. In the illustrated embodiment, the edge coverings 124 cover ends of the top covering 120 and the bottom covering 122. For example, the polymer coating is applied after the top and bottom coverings 120, 122 are affixed to the aerogel blanket 104. In alternative embodiments, the edges 114 may be coated with the edge coverings 124 prior to applying the top covering 120 and the bottom covering 122 such that the top and bottom coverings 120, 122 cover portions of the edge coverings 124.

In other various embodiments, rather than the edge coverings 124 being polymer coatings applied directly to the edges 114, the edge coverings 124 may be defined by a frame or other pre-formed structure used to close off the edges 114. For example, the frame may have a complimentary shape to the aerogel blanket 104 such that the aerogel blanket 104 is set into the frame with the frame closing the edges 114. The frame may be a metal frame and may include a single piece or multiple pieces. The frame may be used to compress the top and bottom 110, 112 of the aerogel blanket 104 when applied thereto. The frame may be used to hold a shape of the aerogel blanket 104 when loaded therein. The frame may be used for mounting the aerogel blanket 104 to another structure. The frame may be a single piece or multi-piece structure. In other various embodiments, the edge coverings 124 may include fasteners used to close the edges and/or provide support for the aerogel blanket 104.

In other various embodiments, the edges 114 may be substantially closed off without the need for another structure at the edges 114. Rather, the stitching 126 used to secure the top and bottom coverings 120, 122 may be pulled tight during the stitching operation to compress the top 110 and the bottom 112 at the edges 114, which may essentially eliminate the edges 114. In such embodiment, the aerogel blanket 104 may be thicker in the central area of the aerogel blanket 104 and may be thinner at the edges 114. The edges 114 may be sufficiently thin such that the top covering 122 may touch or almost tough the bottom covering 122. By reducing the thickness of the edges 114, the amount of dust released from the edges 114 may be reduced.

The stitching 126 may be provided near the edges 114 and/or may be provided remote from the edges 114. For example, the stitching 126 may be provided in a central area of the aerogel blanket 104 to connect the top covering 120 to the bottom covering 122 with the stitching 126 holding aerogel blanket 104 therebetween. The stitching 126 may be provided in any pattern, such as a grid pattern. The stitching 126 may be manufactured from a material capable of withstanding extreme temperatures, such as temperatures of approximately 1,000° C. For example, the stitching 126 may be ceramic fibers, fiberglass, or other types of materials.

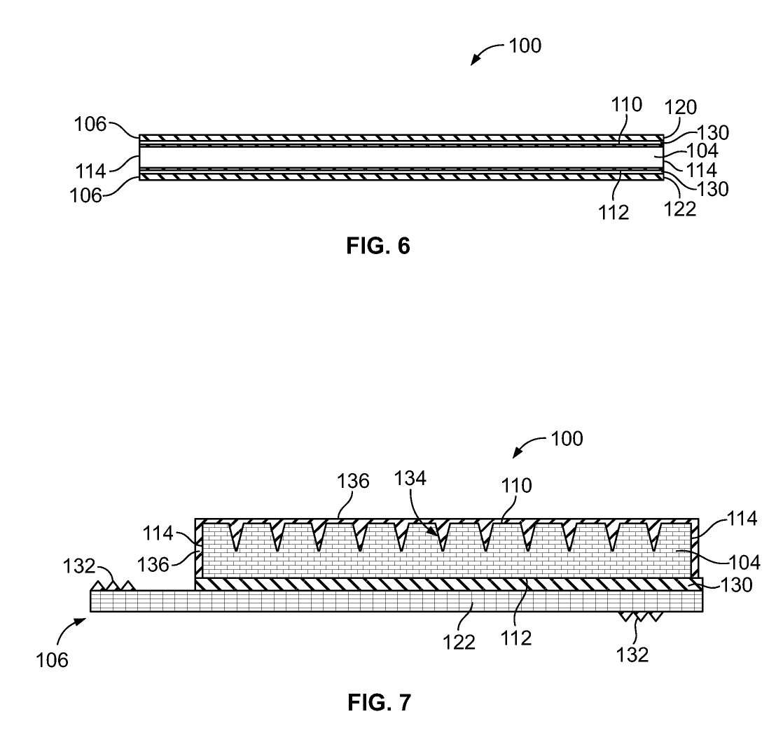

FIG. 6 is a cross-sectional view of the thermal barrier 100 formed in accordance with an exemplary embodiment. The thermal barrier 100 includes the top covering 120 and the bottom covering 122 on the top 110 and the bottom 112, respectively. No edge covering 124 is shown in FIG. 6, however, edge coverings may be provided. In the illustrated embodiment, the top covering 120 is affixed to the top 110 using a hot melt adhesive 130 defining an adhesive layer therebetween. The bottom covering 122 is affixed to the bottom 112 using the hot melt adhesive 130 to define an adhesive layer. The hot melt adhesive 130 may be a fluoropolymer hot melt adhesive. The hot melt adhesive 130 mechanically fixes the coverings 120, 122 to the aerogel blanket 104. In an exemplary embodiment, the adhesive 130 is hydrophobic and inert to act as an oil and water barrier layer for the aerogel blanket 104.

FIG. 7 is a cross-sectional view of the thermal barrier 100 formed in accordance with an exemplary embodiment. The thermal barrier 100 is shown with the bottom covering 122 affixed to the bottom 112. In the illustrated embodiment, the bottom covering 122 is affixed to the aerogel blanket 104 using the hot melt adhesive 130; however, the bottom covering 122 may be affixed by other means, such as sewing the bottom covering 122 to the aerogel blanket 104. The thermal barrier 100 is shown without a top covering, and with the bottom covering 122 extending a distance beyond the aerogel blanket 104.

In an exemplary embodiment, the thermal barrier 100 is configured to be wrapped around the electronic component 102 and may be secured to itself. For example, the thermal barrier 100 may be wrapped around a cable, or other structure, such that the bottom covering 122 covers the electronic component 102 and the aerogel blanket 104. A securing member 132 is provided on the bottom covering 122 for securing the bottom covering 122, such as to itself. For example, the securing member 132 may include hook and loop fasteners. Other types of securing members may be used in alternative embodiments, such as adhesive, fasteners, and the like.

In an exemplary embodiment, the top 110 of the aerogel blanket 104 includes a plurality of v-shaped grooves 134. The grooves 134 allow the aerogel blanket 104 to be folded or wrapped around the electronic component 102. The grooves 134 may discourage wrinkling or tearing of the aerogel blanket 104 as the thermal barrier 100 is wrapper or otherwise applied to the electronic component 102.

In an exemplary embodiment, the aerogel blanket 104 has a coating layer 136 provided thereon. The coating layer 136 may be a polymer coating applied to the aerogel blanket 104. For example, the coating layer 136 may be applied to the top 110 and/or the bottom 112 and/or the edges 114. The coating layer 136 may be applied by dipping, spraying, laminating, or extruding onto the aerogel blanket 104. The coating layer 136 may inhibit dust migration from the aerogel blanket 104. The aerogel blanket 104 may be provided without the coating layer 136 in alternative embodiments, rather relying upon the bottom covering 122 to contain the dust from the aerogel blanket 104.

Embodiments are described herein of a thermal barrier 100 manufactured from an aerogel blanket 104 having excellent thermal properties and workability, such as for handling, bending, cutting, and the like, which allows application to the electrical component 102 and thermal protection of the electrical component 102. The cover 106 protects the aerogel blanket 104 and the electronic component 102 by inhibiting dust formation and/or release from the thermal barrier 100. The cover 106 is capable of withstanding high temperatures and does not suffer from the smoking or discoloration of conventional polymer coatings.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112(f), unless and until such claim limitations expressly use the phrase “means for” followed by a statement of function void of further structure.

What is claimed is:

1. A thermal barrier for an electronic component comprising:
an aerogel blanket configured to cover at least a portion of the electronic component, the aerogel blanket having a top, a bottom and edges therebetween, the bottom configured to face the electronic component; and
a cover positioned between the aerogel blanket and the electronic component, the cover being a structurally reinforcing fabric affixed to the bottom of the aerogel blanket, the cover inhibiting dust migration from the aerogel blanket toward the electronic component.

2. The thermal barrier of claim 1, wherein the cover is sewn to the aerogel blanket.

3. The thermal barrier of claim 1, wherein the cover is affixed to the top of the aerogel blanket, the cover being sewn together through the aerogel blanket.

4. The thermal barrier of claim 1, wherein the cover includes a top covering along the top and a bottom covering along the bottom, the top covering being secured to the bottom covering.

5. The thermal barrier of claim 4, wherein the top covering is sewn to the bottom covering through the aerogel blanket.

6. The thermal barrier of claim 4, wherein at least one of the top covering and the bottom covering wrap around the edges of the aerogel blanket to secure to the other of the bottom covering or the top covering.

7. The thermal barrier of claim 4, wherein the top covering is affixed to the aerogel blanket independent of the bottom covering being affixed to the aerogel blanket.

8. The thermal barrier of claim 4, wherein the top covering is affixed to the top using hot melt adhesive and the bottom covering is affixed to the bottom using hot melt adhesive.

9. The thermal barrier of claim 1, wherein the cover completely encloses the aerogel blanket.

10. The thermal barrier of claim 1, wherein the cover is a fiberglass fabric.

11. The thermal barrier of claim 1, wherein the cover is a ceramic fabric.

12. The thermal barrier of claim 1, wherein the cover is an inorganic film.

13. The thermal barrier of claim 1, further comprising stitching through the aerogel blanket and the cover to affix the cover to the aerogel blanket.

14. The thermal barrier of claim 1, wherein the aerogel blanket and the cover are flexible to allow the thermal barrier to change shape.

15. The thermal barrier of claim 1, wherein the cover includes edge coverings along the edges.

16. The thermal barrier of claim 15, wherein the edge coverings are polymer coatings at the edges.

17. The thermal barrier of claim 15, wherein the edge coverings are a frame holding the aerogel blanket and portion of the cover along the bottom.

18. The thermal barrier of claim 15, wherein the edge coverings are structurally reinforcing fabric.

19. A thermal barrier for an electronic component comprising:
an aerogel blanket configured to cover at least a portion of the electronic component, the aerogel blanket having a top, a bottom and edges therebetween, the bottom configured to face the electronic component; and
a cover affixed to the aerogel blanket such that the cover is positioned between the aerogel blanket and the electronic component, the cover having a top covering along the top of the aerogel blanket and the cover having a bottom covering along the bottom of the aerogel blanket, the top cover being sewn to the bottom cover through the aerogel blanket, the cover inhibiting dust migration from the aerogel blanket to the electronic component.

20. A thermal barrier for an electronic component comprising:
an aerogel blanket configured to cover at least a portion of the electronic component, the aerogel blanket having a top, a bottom and edges therebetween, the bottom configured to face the electronic component; and
a cover affixed to the aerogel blanket such that the cover is positioned between the aerogel blanket and the electronic component, the cover having a top covering along the top of the aerogel blanket, the cover having a bottom covering along the bottom of the aerogel blanket, the cover having an edge coating along the edges of the aerogel blanket between the top covering and the bottom covering, the cover inhibiting dust migration from the aerogel blanket to the electronic component.
